(19) United States
(12) Patent Application Publication
(10) Pub. No.: US 2017/0363689 A1
(43) Pub. Date: Dec. 21, 2017

(54) Accelerated Testing Protocols For Solid Oxide Fuel Cell Cathode Materials

(71) Applicant: University of South Carolina, Columbia, SC (US)

(72) Inventors: Xiao-Dong Zhou, Irmo, SC (US); Emir Dogdibegovic, Cayce, SC (US)

(21) Appl. No.: 15/622,596

(22) Filed: Jun. 14, 2017

Related U.S. Application Data
(60) Provisional application No. 62/350,931, filed on Jun. 16, 2016.

(51) Int. Cl. G01R 31/36; H01M 4/90; H01M 8/124

(52) U.S. Cl. CPC G01R 31/3631; H01M 4/9033; H01M 2008/1293

(57) ABSTRACT

Accelerated testing protocols that can be utilized for determining and projecting the durability of SOFC cathodes are described. The accelerated testing protocols can be carried out under simulated operation conditions so as to provide in a matter of a few hundred hours data that can correlate to the condition of the cathode following operation of the cell over the course of a typical operation life span of several thousand hours. A testing protocol can include cycling a SOFC from OCV to operating potential at a predetermined current density. Each cycle can be relatively short, for instance less than one minute.

### CROSS REFERENCE TO RELATED APPLICATION

This application claims filing benefit of U.S. Provisional Patent Application Ser. No. 62/350,931, having a filing date of Jun. 16, 2016, which is incorporated herein by reference for all purposes.

### GOVERNMENT SUPPORT CLAUSE

This invention was made with government support under grant no. DE-FE0026097 awarded by the Department of Energy National Energy Technology Laboratory. The government has certain rights in the invention.

### BACKGROUND

Fuel cell technologies present intriguing alternatives to conventional fossil fuel-based combustion technologies and are quickly becoming a mainstay in sustainable clean energy applications. Fuel cells can produce lower levels of pollution, higher electrical efficiency and potentially have lower long-term operating costs as compared to more conventional technologies. Moreover, fuel cells can utilize various fuels including hydrogen, natural gas, biogas, syngas, and reformed fuels (diesel, kerosene). As such, fuel cell technology can also form a link between current energy supply systems based on fossil fuels and future development on the basis of renewable, pollution-free gaseous and liquid fuels.

Solid oxide fuel cells (SOFCs) are characterized by having a solid ceramic electrolyte, which eliminates the electrolyte corrosion and liquid management problems typically associated with other types of fuel cells. SOFCs operate at a high temperature (typically about 600° C. to about 1000° C.), and the efficiency of SOFC in converting fuel to electricity can be as high as 50-60%. SOFCs can also take advantage of a waste heat cogeneration system, use of which can increase fuel cell efficiency to 80-90%. In addition, SOFC ceramics are not sensitive to carbon monoxide, which means CO can optionally be used as fuel.

One of the key issues hindering wider adoption of SOFCs is the lifetime of the materials in the operating environment. Microstructure changes in the ceramics that form SOFCs is one of the main forms of degradation during long-term operation of the high temperature fuel cells. Microstructural changes such as densification and particle coarsening lead to a decrease of the triple phase boundary (the collection of sites where the electrolyte, the electron-conducting phase, and the gas phase all come together) as well as a loss of percolation and hindered diffusion.

A long-lasting challenge in SOFC R&D is a lack of useful test protocols to examine potential SOFC materials for degradation characteristics such as microstructural changes. Operation of SOFCs under normal conditions for tens of thousands hours is often impractical and costly and as such, reliable accelerated test protocols are needed to facilitate rapid learning on key durability and reliability issues. Successful accelerated test protocols must ensure that there are no new failure mechanisms introduced that would be unrealistic in a real SOFC environment and that there are detailed and reliable examinations performed on the tested materials that can be compared to steady-state operation providing reproducible baselines.

What are needed in the art are accelerated testing protocols for SOFC materials. Advances in SOFC technology that can be obtained through improved accelerated testing protocols are critical to achieving SOFC enhancements including improving the robustness and durability of the fuel cells as well as increasing performance at lower operation temperatures.

### SUMMARY

According to one embodiment, disclosed are accelerated testing protocols for SOFC cathode materials. A testing protocol can include cycling a SOFC multiple times between an open circuit voltage (OCV) and an operating potential. In one embodiment, the current density can be the primary parameter of the testing protocol. For instance, the operating current density of each cycle can be about 0.15 Amps per square centimeter (A/cm²) or greater. In another embodiment, the cycle frequency can be the primary parameter of the testing protocol. For instance, a single cycle can include a first time period at the OCV and a second time period at the operating potential, with the time period at the operating potential being about 1 minute or less and being greater than the time period at the OCV. For example, the ratio of the time spent at the operating potential to the time spent at the OCV can be about 5:1 or less.

A testing protocol can be carried out for a relatively short period of time and/or number of cycles. For example, a testing protocol can be carried out over total time period of about 500 hours or less, or about 500,000 cycles or less in some embodiments. Other testing parameters as may be varied can include testing temperature, atmospheric characteristics, structural design, materials of formation, etc.

Following the testing protocol, the cathode materials can be examined by any of a variety of different methodologies to provide data with regard to cathode response in a typical long-term, high temperature environment.

### BRIEF DESCRIPTION OF THE FIGURES

A full and enabling disclosure of the present invention, including the best mode thereof, directed to one of ordinary skill in the art, is set forth in the specification, which makes reference to the appended figure, in which:

FIG. 1 schematically illustrates a planar SOFC.

FIG. 2 schematically illustrates a tubular SOFC.

FIG. 3 presents an exemplary plot of measurements as may be conducted in a test protocol. The graph at (a) shows that it is beneficial to measure impedance at certain current density, which can be cross-checked by analyzing i-E sweep. The graph at (b) is a plot of electrochemical impedance spectra (EIS) as a function of time. The lower graph illustrates the change power density over time and beneficial testing periods for different measurements of a testing protocol.

FIG. 4 illustrates the differential relaxation time (DRT) spectra at (a) for a fuel cell and derived from impedance spectra (b) measured in both fuel cell and electrolyzer modes.

FIG. 5A is a cross sectional image of a typical lanthanum strontium cobalt ferrite-based (LSCF) single cell as can be utilized for accelerated tests. The inserted image is an Au-grid on an LSCF cell.

FIG. 5B presents the electrochemical performance of an LSCF cathode measured every 50 hours at 750° C. in a testing protocol including 25 sec @ 1 A/cm² and 5 sec @ OCV.

FIG. 5C presents the electrochemical performance of an LSCF cathode measured every 50 hours at 750° C. in a testing protocol including 2 sec @ 1 A/cm² and 1 sec @ OCV.

FIG. 5D, FIG. 5E, and FIG. 5F are initial EIS spectra measured at various times for different LSCF testing protocols including 25 sec @ 1 A/cm² and 5 sec @ OCV (FIG. 5D), 2 sec at 0.5 A/cm² and 1 sec @ OCV (FIG. 5E) and 2 sec @ 1 A/cm² and 1 sec @ OCV (FIG. 5F).

FIG. 5G, FIG. 5H, and FIG. 5I are analyses of the concentration of Sr at the interfaces between YSZ and doped ceria for different LSCF cathodes following testing protocols as described herein.

FIG. 6A illustrates the electrical performance of a PNNO cathode over the course of a testing protocol as described herein.

FIG. 6B illustrates the electrical performance of a PNNO cathode over the course of another testing protocol as described herein

### DETAILED DESCRIPTION

The following description and other modifications and variations to the present subject matter may be practiced by those of ordinary skill in the art, without departing from the spirit and scope of the present disclosure. In addition, it should be understood that aspects of the various embodiments may be interchanged in whole or in part. Furthermore, those of ordinary skill in the art will appreciate that the foregoing description is by way of example only, and is not intended to limit the disclosure.

In general, disclosed herein are accelerated testing protocols that can be utilized for determining and projecting the durability of SOFC cathodes. The accelerated testing protocols can be carried out under simulated operation conditions so as to provide in a matter of a few hundred hours data that can correlate to the condition of the cathode following operation of the cell over the course of a typical operation life span of several thousand hours. For example, an accelerated test can be carried out over a time period of from about 200 hours to about 500 hours on a single cell with an active area of about 2 square centimeters (cm²) over a typical operational temperature range (e.g., about 600° C. to about 870° C.), and this testing protocol can successfully simulate a steady-state SOFC operation for approximately 2,000 to approximately 40,000 hours.

The general testing protocol includes cycling a SOFC formed to include the desired cathode from OCV to the operating potential at a predetermined operating current density and for relatively short cycles to accelerate the cathode performance. According to one embodiment, a primary parameter for the cycling can be the cell operating current density utilized during the protocol. The cell operating current density utilized during a testing protocol can generally be about 0.15 A/cm² or greater, for instance from about 0.15 A/cm² to about 3 A/cm², or from about 0.5 A/cm² to about 2 A/cm² in some embodiments.

In one embodiment, a testing protocol can include carrying out the cycling protocol multiple times at different operating current densities. For instance, a cell can be cycled from 0 A/cm² at various loadings, e.g., about 0.5 A/cm², about 1 A/cm², and 1.5 A/cm² and the cathode can be examined for aging characteristics after each cycling protocol.

The testing protocols also utilize a relatively short cycle frequency for both the OCV time period and the operating potential time period. In general, the time period of a single cycle spent at the operating potential can be about 1 minute or less. For instance, a cycle can include a step at the predetermined load of about 50 seconds or less, for instance from about 2 seconds to about 50 seconds in some embodiments. A step at the operating potential load can be, e.g., about 50 seconds, about 30 seconds, about 20 seconds, about 10 seconds, about 5 seconds, or about 2 seconds, in some embodiments.

The time period of a cycle at the OCV can generally be shorter than the time step of the cycle at loading. For instance, the ratio of the time at load to the time at OCV can be from about 2:1 to about 10:1, for instance about 4:1 or about 5:1, in some embodiments. By way of example, a step at OCV can be, e.g., about 10 seconds or less, for instance from about 1 second to about 10 seconds in some embodiments. A step at OCV can be, e.g., about 10 seconds, about 5 seconds, about or about 1 second, in some embodiments.

Depending upon the cathode material, in some embodiments the current density loading can play a more significant role in cathode behavior over time as compared to other parameters such as the cycling frequency. Accordingly, when testing such materials it may be beneficial to carry out a protocol at several levels of operating current density. For example, when examining cathodes based upon nickelates, the cyclic loading (current density) can play a more significant role in cathode aging than the cycle frequency, and as such a testing protocol can include cycling at multiple different levels of loading.

For other cathode materials, such as perovskite-type cathodes, the cycling frequency can play a key role on the cathode aging characteristics, e.g., the segregation and transformation kinetics. In such a testing protocol, it may be beneficial to examine the materials under multiple different cycle frequencies. For instance, multiple testing protocols can be carried out with the SOFC at different loading step times, e.g., 2, 5, 20, and 50 seconds. Moreover, each protocol in which the cycle time is varied from one protocol to another can be carried out at the same or at different current densities so as to obtain data with regard to the expected aging of the cathode.

A single cycling protocol (e.g., identical step times and current density load throughout) can generally be carried out for a total time of about 2,000 hours of operation or less, for instance from about 200 hours to about 2,000 hours in some embodiments. Depending upon the particular time periods of each cycle, this can generally correlate to a total cycle number of about 500,000 or less.

A testing protocol can generally be carried out at or near an expected temperature of operation for the SOFC. For instance, when testing a perovskite-type cathode such as LSFC-based cathodes, the testing temperature(s) can be based on an expected operation temperature of about 750° C. and can take into consideration inlet and outlet temperature variations. For example, an SOFC including a perovskite-type cathode can be tested at about 650° C., about 750° C., and/or about 850° C. Other cathode materials may be tested at different temperatures. For instance nickelate cathode materials may be tested at somewhat higher temperatures such as, e.g., 700° C., 790° C., and/or 870° C. In general, a cathode can be tested at one or more temperatures that can be ±about 100° C. of an expected operating temperature.

Other parameters that can be varied for a testing protocol can include, without limitation, the testing atmosphere, the fuel/oxidant flow components, and the active area of the SOFC components, and in particular the active area of the cathode.

By way of example and without limitation, the testing atmosphere on either side of the fuel cell can be varied with regard to relative humidity, inert and/or potentially reactive species present in the fuel/oxidant flow, and so forth. In one embodiment, the relative humidity level in one or both of the fuel and oxidant flow can be varied. For instance, the relative humidity of a fuel and/or oxidant flow can be varied from 0% humidity to about 10% relative humidity or from about 1% to about 3% relative humidity in some embodiments.

In one embodiment, one or more volatile species can be included in the fuel and/or oxidizer stream. For instance, in one embodiment volatile chromium can be included in the oxidizer stream. Volatile chromium species are a common SOFC contaminant species that can enter the SOFC system from steel pipes or interconnects and can react with the cathode, and subsequently decrease the cathode activity. As such, a testing protocol that includes the potential effect of a contaminant species can be of benefit in examining the efficacy of the cathode material over long-term use.

The active area of the cathode can be of any convenient size. For instance, the active area of a single SOFC cathode can be about 1 cm² or greater, or about 2 cm² or greater in some embodiments. The total active cathode area of a testing protocol can be from a single SOFC or a stacked design, as is known in the art. For instance, accelerated test protocols can be utilized to test single cells with an active area of 2 cm², 10 cm², 25 cm², 50 cm², 63 cm², etc.

Any known or experimental cathode material may be examined by use of the disclosed testing protocols. By way of example, and without limitation, cathodes as may be examined can be lanthanum based, gadolinium based, praseodymium based, strontium based, or yttria based. A non-limited list of lanthanum-based cathode materials can include, for instance, LSCF materials such as La_{0.60}Sr_{0.40}Co_{0.20}Fe_{0.80}O₃ (LSCF6428), lanthanum strontium manganite materials (LSM or LSMO) such as La_{0.79}Sr_{0.20}MnO₃ (LSM20), lanthanum strontium ferrite materials (LSF), lanthanum strontium cobalt materials (LSC), lanthanum strontium manganite cobalt materials (LSMC), e.g., La₁₋ₓSrₓMn_{0.96}Co_{0.04}O₃, lanthanum strontium manganite chromium materials (LSMCr), lanthanum calcium manganite materials (LCM), strontium-doped lanthanum copper oxides (LSCu) such as La₁₋ₓSrₓCuO_{2.5-δ}, lanthanum nickel oxide materials (LNO), ferrite-doped lanthanum nickel oxide materials (LNFO), and so forth.

Praseodymium based cathode materials can include, without limitation, praseodymium calcium manganite materials (PCM) such as (Pr_{0.7}Ca_{0.3})_{0.9}MnO₃, praseodymium strontium manganite materials (PSM), barium-doped praseodymium cobalt materials (PBC) such as PrBaCo₂O_{5+δ}, and so forth. In one embodiment, a cathode that can be tested by the protocols can include a praseodymium-nickelate based material having a general formula of (Pr₁₋ₓ Aₓ)ₙ₊₁(Ni_{1-y})B_{y})ₙO_{3n+1+δ} in which A is at least one metal cation of La, Nd, Sm or Gd; B is at least one metal cation of Cu, Co, Mn, Zn, or Cr; 0<x<1; and 0<y<0.4. Such materials have been described for example in U.S. Published Patent Application No. 2016/0020470 to Jung, et al., which is incorporated herein by reference. One particular example of such a cathode material is doped (Pr_{0.50}Nd_{0.50})₂NiO₄ (PNNO5050).

Other exemplary cathode materials can include, without limitation, gadolinium strontium cobalt materials (GSC) such as Gd_{0.6}Sr_{0.4}CoO₃, gadolinium strontium manganite materials (GSM), samarium strontium cobalt materials (SSC) such as Sm_{0.5}Sr_{0.5}CoO₃₋ₓ, ferrite barium strontium cobalt materials (BSCF) such as Ba_{0.5}Sr_{0.5}Co_{0.8}Fe_{0.2}O_{3-δ}, ferrite yttria strontium cobalt materials (YSCF) such as Y₍₁₋ₓ₎SrₓCo_{y}Fe_{(1-y)}O₃, ferrite yttria calcium cobalt materials (YCCF) such as Y₍₁₋ₓ₎CaₓCo_{y}Fe_{(1-y)}O₃, and so forth.

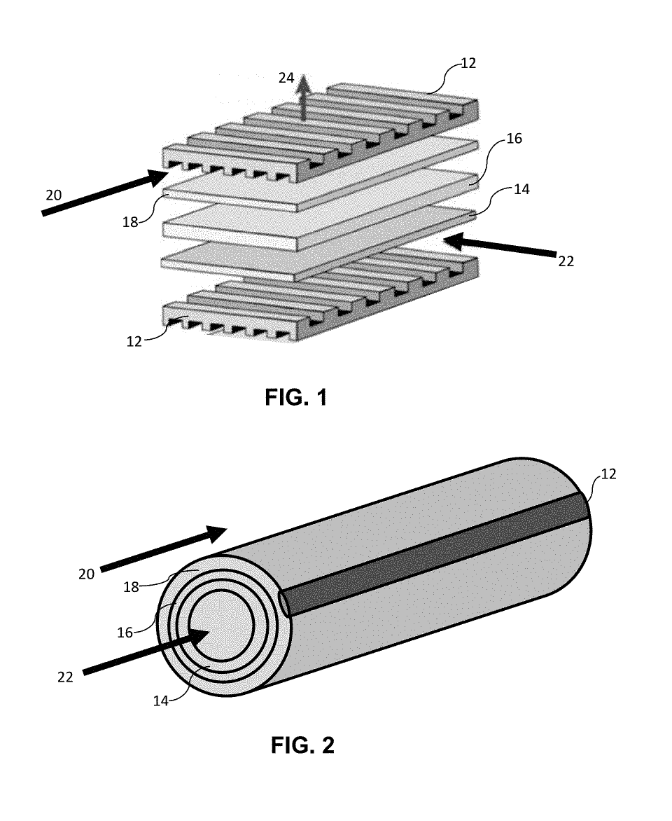

SOFC cathodes as may be examined by the accelerated testing protocols can be components of any sort of SOFC or SOFC system. By way of example, an SOFC cathode as may be tested according to the protocols can be a component of planar SOFC as illustrated in FIG. 1 or a tubular SOFC as illustrated in FIG. 2. As shown, both planar tubular SOFCs include a cathode 14, electrolyte 16, anode 18, and interconnect 12. Fuel flow 20 (e.g., one or a mixture of hydrocarbons, H₂, CO, etc.) contacts the anode 18 and oxidizer flow 22 (generally air) contacts the cathode 14 (also commonly called the air electrode). Planar SOFC designs (FIG. 1) are distinguished by having a higher volumetric power density, better electrical performance, and lower initial costs as compared to tubular designs due to the utilization of lower cost fabrication methods like tape casting, slurry coating, screen printing or other deposition techniques. However, the tubular design (FIG. 2) has fewer problems with temperature gradients or with low volumetric power density due to the long circumferential current paths in the electrodes.

Any cell design is encompassed herein. For instance, tubular designs can be of any flattened tubular or microtubular designs as are generally known in the art. SOFCs as may be tested for cathode performance can be self-supporting or external supporting. In the self-supporting group, any of the cell components can act as the structural support of the cell, examples of which include electrolyte-supported, anode-supported and cathode-supported. As such, the structural support will generally be the thickest layer in an individual cell. In contrast, the external-supporting SOFCs can be configured as a thin layer on an interconnecting or porous substrate. Moreover, SOFCs as may be tested can be single cell or SOFC stacks. In the stack design, individual cells can be connected together in series, parallel or both.

The SOFC to be tested can include other components as are generally known in the art, with preferred materials generally depending upon the cathode material to be tested. By way of example, and without limitation, the SOFC can include an electrolyte that can include one or more of a zirconia based material (e.g., YSZ, SSZ, CaSZ), a ceria-based material (e.g., GDC, SDC, YDC, CDC), a lanthanum based material (e.g., LSGM, LSGMC, LSBMF, LSGMDF), or other electrolyte materials as are known in the art (e.g., BCY, YSTh, YSHa, bismuth-oxide based, pyrochlorores-based, barium brownmillerites, strontium brownmillerites, etc.).

Typical anode materials can include, without limitation, nickel based materials such as NI-O/YSZ, Ni—O/SSZ, Ni—O/GDC, Ni—O/SDC, Ni—O/YDC; copper based materials such as Cu/O₂/CeO₂/YSZ, CuO₂/YSZ, Cu/YZT, CuO₂/CeO₂/SDC; lanthanum based materials such as La₁₋ₓSrₓCrO₃, La₁₋ₓSrₓCr_{1-y}M_{y}O₃, LST, LAC; and other materials such as CeO₂/GDC, TiO₂/YSZ, cobalt based materials, platinum based material, Ru/YZ; and so forth.

Typical interconnect materials can include, without limitation, chromium alloys, ferritic stainless steels, austenitic stainless steels, iron super alloys, nickel super alloys, coatings including one or more of LSM, LCM, LSC, LSFeCo, LSCr, LaCoO₃, lanthanum chromite ceramics, and so forth.

When included, seals can be formed of glass or glass-ceramic materials, mica-based composites, and the like.

During and/or following the accelerated cycling testing protocols, examination of the SOFC/cathode can be carried out to determine aging characteristics of the cathode. By way of example and without limitation, examination protocols can include X-ray photoelectron spectroscopy (XPS), transmission electron microscopy (TEM), scanning electron microscopy (SEM) such as focused ion beam SEM (FIB-SEM), and the like. Analysis techniques can be utilized to examine microstructures, elemental mapping, oxidation states of transition metal ions, etc., which can provide information with regard to the aging characteristics of the cathode. For instance, in-situ XPS has been extensively used in a wide variety of analysis applications and has been found very valuable in providing information concerning the valences and resident defects in oxides by catalysis groups.

In one embodiment, the SOFC can be examined via elemental mapping or the like post-testing to determine segregation of dopants contained in the cathode. For instance, strontium segregation can be analyzed at one or both of the cathode/electrolyte interface and at the surface of the cathode.

Power density profiles of the cathode can optionally be determined, for instance as a function of current density and/or of time and/or by comparing the cell performance at the beginning and end of the cycles.

Electrochemical impedance spectroscopy (EIS) can be carried out to provide information with regard to the cathode ageing. For instance, EIS can be measured at various current densities periodically throughout a testing protocol, for instance every 50 hours, or every 100 hours, in some embodiments. In one embodiment, the electrode activity determined from EIS spectra can be measured with various external loads, for instance external loads that are found to play an important role in measurements. In order for EIS to better focus on and investigate electrode dynamics of the cathode, the anode contribution can be separated from EIS spectra.

In one embodiment, the polarization curve (i-E curve) can also be measured, for instance before EIS is measured. As the operating conditions (e.g. current density) not only influence cathode durability, but also the measurements of degradation effects, it may be beneficial to use galvanostatic modes to measure the cell with a relatively low initial current density, e.g., of 0.4 A/cm², 0.6 A/cm² or 1.0 A/cm². An even lower initial current density, e.g., about 0.25 A/cm² can optionally be applied at lower temperatures using some inactive cathodes. The polarization curve can generally be determined throughout a testing protocol, for instance, every 50 hours of testing, or every 100 hours of testing, in some embodiments.

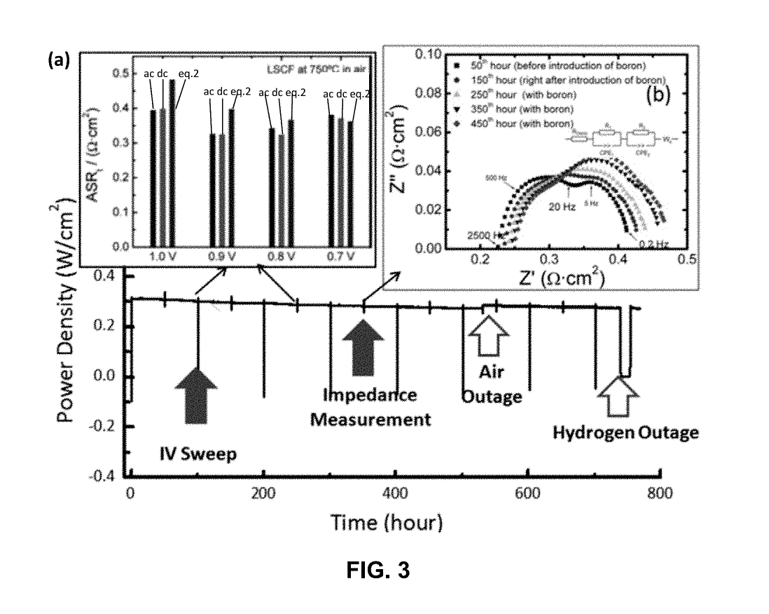

FIG. 3 presents an exemplary plot of i-E sweep and impedance measurements as may be made in a testing protocol. This particular plot was developed based upon measurement of i-E sweep every 100 hours of a testing protocol and impedance response measured at every 50^{th} hour of a testing protocol. The figure at (a) shows that it is necessary to measure impedance at the correct current density, which can be cross-checked by analyzing i-E sweep. The figure at (b) is a plot of EIS as a function of time, from which differential relaxation time (DRT) analysis (described further below) can be carried out.

FIG. 3 shows the spectra of a single cell with LSCF cathode measured at 600° C. in air. The depressed arc at (b) represents electrode resistance, which decreases with decreasing external load, suggesting that the electrode activity is dependent on the field.

Area specific resistance (ASR) can be used to characterize the evolution of particular areas of a cathode during a testing protocol. ASR analysis can, for instance, provide a route to select particular regions for future research. In one embodiment, ASR value can be measured by EIS at a specific operating voltage (e.g. 0.7 V). Moreover, ASR can be cross validated by both ac EIS and dc current-potential (i-E) sweep. ASR can generally be determined periodically throughout at testing protocol, for instance every 50 hours, or every 100 hours in some embodiments.

DRT analysis can be used to deconvolute the temporal evolution of physical and chemical processes shown in measured impedance spectra. For example, DRT and post analysis (e.g., complex nonlinear least square fitting) can be utilized to deconvolute contributions from the anode, cathode, and gas diffusion to the overall cell resistance and can be utilized to pinpoint locations of cell degradation in terms of microstructural evolution of the electrodes and decrease of electrocatalytic activity.

DRT analysis is an advantageous approach for SOFC R&D as it can provide direct access to the kinetic parameters of the underlying processes in both cathode and anode. In addition, DRT analysis does not require any priority choice of an equivalent electrical circuit models with subsequent nonlinear least squares curve fit. Moreover, DRT analysis can overcome the poor resolving frequency capacity inherent to equivalent circuit models and it can provide a clearer picture of SOFC operation, which allows for distinguishing of loss factors to either the anode or the cathode side, and thus better target fuel cell development. Beneficially, DRT analysis can also be used to analyze a variety of configurations and size of SOFCs.

The essence of DRT analysis is to conduct Fourier transformation of the impedance data. It is known that in an impedance spectrum diffusion processes overlap with charge exchange and transfer processes. As such, an individual impedance spectrum related to SOFC operation cannot be deconvoluted by a conventional “semi-equivalent circuit” model. A Fourier transformation allows the direct calculation of a distribution function of relaxation times and amplitudes of impedance-related processes straight from experimental data. Each electrode process can be separated from a DRT spectrum if the neighboring electrode processes have a relaxation frequency difference of about half a decade.

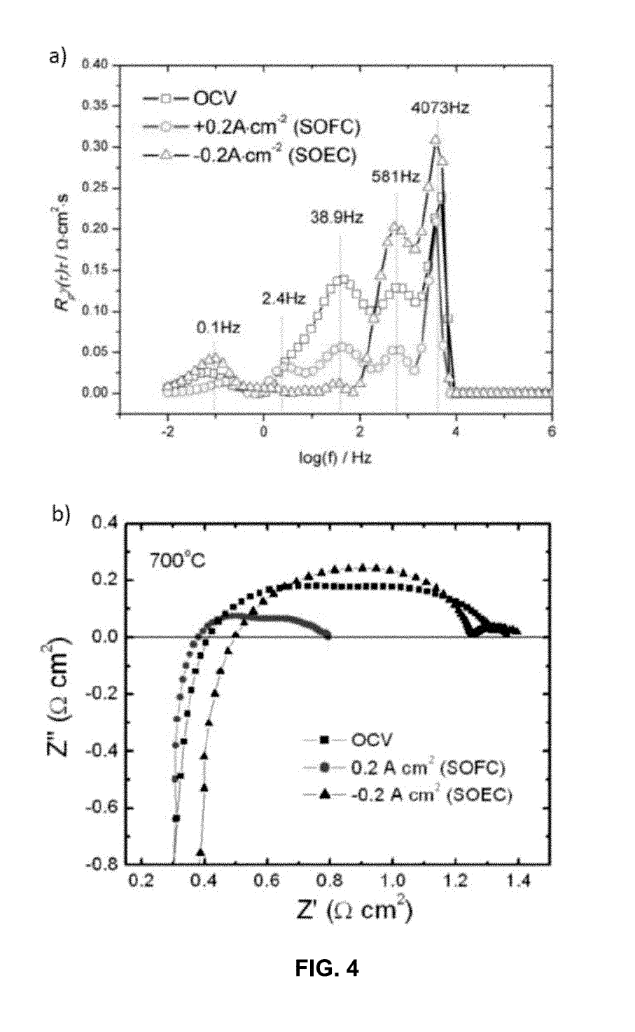

FIG. 4 at (a) illustrates DRT spectra derived from the imaginary part of the impedance data of a solid oxide cell operating at three different current densities at 700° C. (FIG. 4 at b). There are clearly five distinct arcs over a frequency range from 0.01 Hz to 10k Hz, while there is only a depressed arc in the original impedance spectra. A DRT spectrum indicates the relationship between Rₚγ(τ)τ and log(f), where Rₚ is the total polarization resistance; f is the relaxation frequency; τ is the relaxation time, τ=½πf; γ(τ) is the ratio between the resistance corresponding to relaxation time τ and the total polarization resistance, γ(τ)=R(τ)/Rₚ.

In a generic DRT spectrum, the area enclosed by a DRT peak stands for the polarization resistance corresponding to some electrode process under logarithmic real scale log(f). DRT analysis of impedance spectra can be carried out to obtain a distribution as shown in FIG. 4 at a). As shown in in FIG. 4, in order to identify the origin of these peaks, impedance data must be acquired, e.g., from about 0.01 to about 10 kHz. A series of impedance spectra can be obtained through measurement with various external loads (e.g. 0.4<V<OCV), temperature, and fuel and oxidant compositions and utilizations. Previous work has shown that the electrode resistance decreases with decreasing external load, suggesting that the electrode activity is dependent on the field. DRT analysis can be carried by combing the least square fitting and the shape, magnitude, and characteristic frequencies of impedance spectra to relate ASR with cell properties, including component microstructures, constituent chemistry, cell geometry and operating conditions.

Dilute gases (e.g., nitrogen or helium) can be used to investigate the contribution of concentration polarization in cathode, because of the difference in the effective binary diffusivities (e.g., N₂/O₂ vs. helium/O₂). It should be pointed out that a good DRT spectrum can be achieved only when the impedance spectrum obeys the Kramers-Kronig transformation, which practically requires a quite smooth impedance spectrum in the upper half-plane of impedance diagram (negative imaginary part) while in the high-frequency region, the inductive impedance often observed in the lower half-plane of impedance diagram (positive imaginary part) can hide some real cell impedance responses. The inductive impedance mainly comes from the contact lead wires or cell test fixtures. The inductive impedance generally must be taken into consideration for a better fitting and DRT analysis. The high frequency region can for example be measured around 10 points (typically up to 500 kHz for a button cell).

In the illustrated exemplary case of FIG. 4, the DRT spectrum at (a) illustrates five observed peaks at 0.1, 2.4, 38.9, 581, and 4073 Hz that can be designated as P1 to P5, respectively. Such a relaxation times distribution pattern is typical for an anode supported button cell. At the anode side, the peaks at 2.3 kHz, 581 Hz, and 4.1 Hz are associated with the ionic transport, charge transfer, and gas diffusion, respectively. The peak at 16.2 Hz represents oxygen surface exchange and bulk diffusion in the cathode, while the contribution of cathode gas diffusion is attributed to the peak at 0.1 Hz. The distribution of the peaks in such a DRT plot can serve as a framework for analysis to pinpoint the evolution of microstructure and activity at both cathode anode sides of a SOFC examined by a protocol as disclosed herein.

The disclosed subject matter may be better understood with reference to the Examples, set forth below

### Example 1

### Cell Fabrication

Anode-supported electrolyte membranes were fabricated through a non-aqueous tape-casting and lamination process. The bulk anode was prepared using a mixture of NiO and YSZ formulated to yield 40 vol. % each of Ni and 60 vol. % YSZ in the reduced anode. The functional anode layer was formulated for a final composition of 50 vol. % for both Ni and YSZ in reduced functional anode layer. Green tapes of the electrolyte (YSZ), functional anode layer and bulk anode layer were laminated together and then co-sintered in air. The sintering heat treatment consisted of ramping from room temperature to 180° C. (0.5° C./min) and holding for 1 hour for the decomposition of the binder, ramping to 380° C. (1° C./min) and holding for 1 hour to burn off the binder residue, and then ramping to 1450° C. (1° C./min) and holding for 1 hour to densify the electrolyte. The sintered bilayers were subsequently creep-flattened in air at 1350° C. for 2 hours. After sintering, the thickness and diameter of the bilayers were approximately 1 mm and 25 mm, respectively, with a dense electrolyte membrane (˜8 μm thick).

Bimodal Ce_{0.8}Sm_{0.2}O_{1.9} (SDC-20) powders (5 nm and 100 nm) were obtained from ffuelcellmaterials (FCM) and were used as the raw powders to make inks for doped ceria layer via screen printing. The SDC-20 interlayers were co-sintered with the anode current collector (Ni mesh embedded in NiO paste) at 1200° C. for 2 hours.

Inks containing (La_{0.60}Sr_{0.4}O)(Co_{0.20}Fe_{0.80})O₃ (LSCF6428) powders were applied by screen-printing (1.6 cm diameter print) and then sintered at 900° C. The cathode area after sintering, 2 cm², was used as the active cell area to calculate power density and areal specific resistance (ASR). The cathode contact for LSCF was La_{0.79}Sr_{0.20}CoO₃ (LSC). A combination of gold mesh and foil was used on the top of the cathode contact, and were pressed into the wet cathode contact ink prior to heat up. The cells were sealed to alumina test fixtures using G18 glass sintered at 800° C./1 h, and a compressive load (˜2-10 psi) was applied to the cell via a perforated alumina stub which was spring loaded outside the furnace hot zone.

It was found that use of an Au grid with an open area of ˜40% was capable of yielding reliable baseline for quantifying the phase transformation and segregation kinetics. More importantly, it was found that x-rays could penetrate through the Au grid with a proper thickness. Hence, the phases were compared with standard Au before and after cycling.

The cycling profiles for three LSCF6428 electrodes were:

LSCF-I was operated at 1 A/cm² for 25-sec, then switched to 0 A/cm² for 5-sec.

LSCF-II was operated under fast cycling at 0.5 A/cm² loading for 2-sec, followed by 1-sec at 0 A/cm².

LSCF-III was operated under fast cycling at 1 A/cm² loading for 2-sec, followed by 1-sec at 0 A/cm².

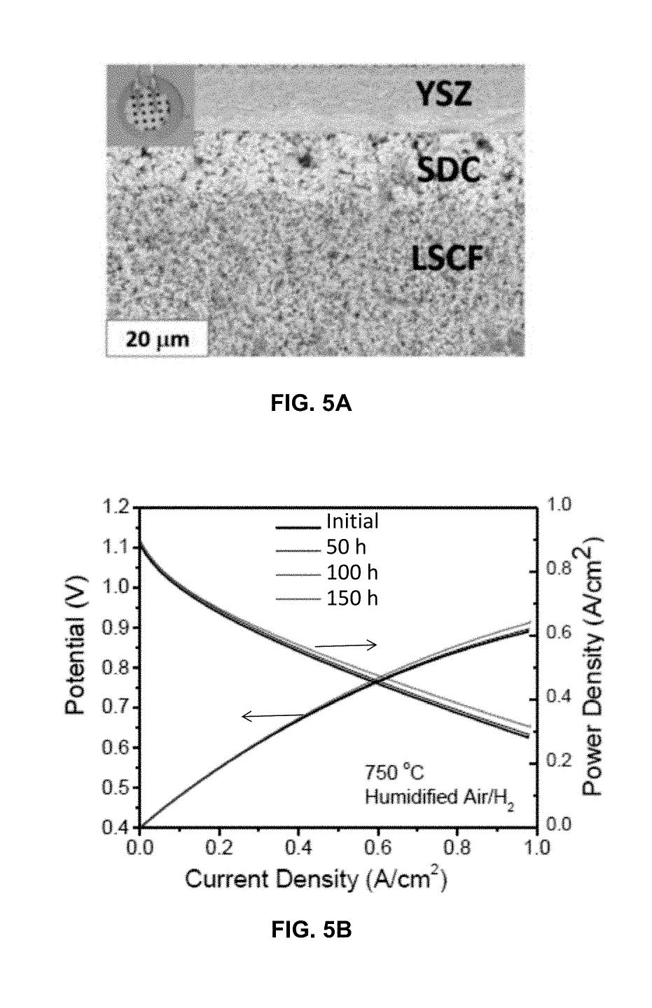

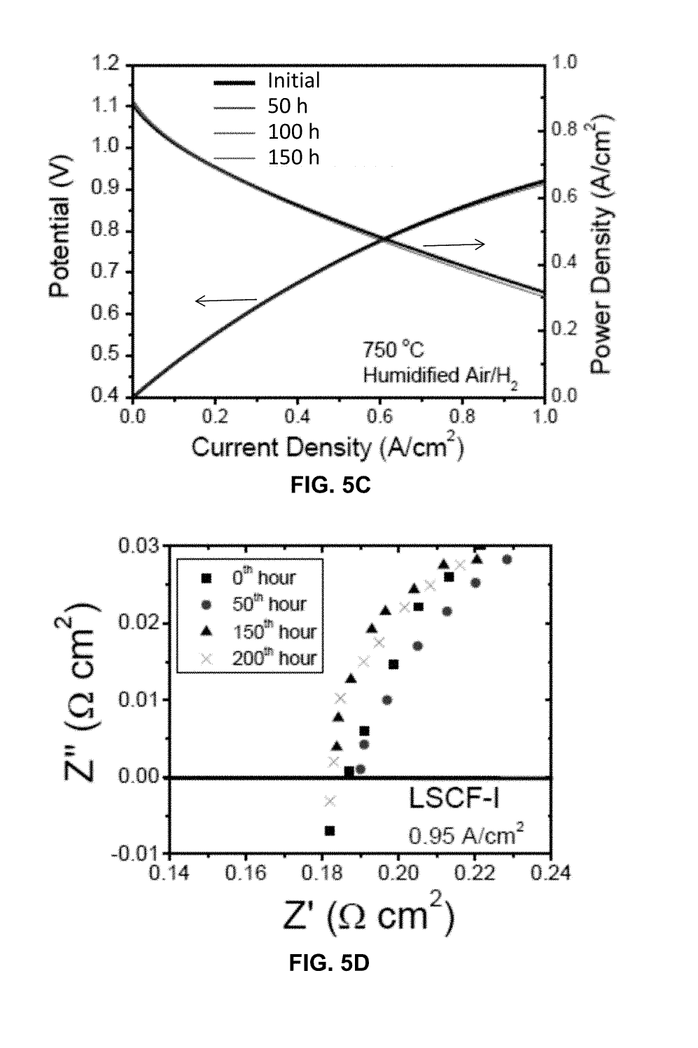

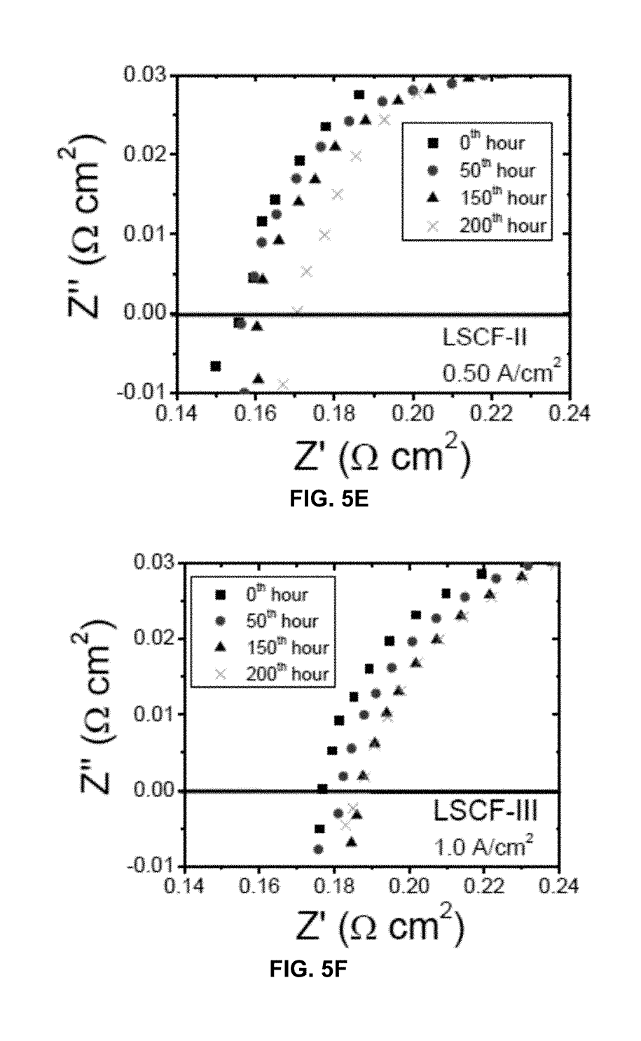

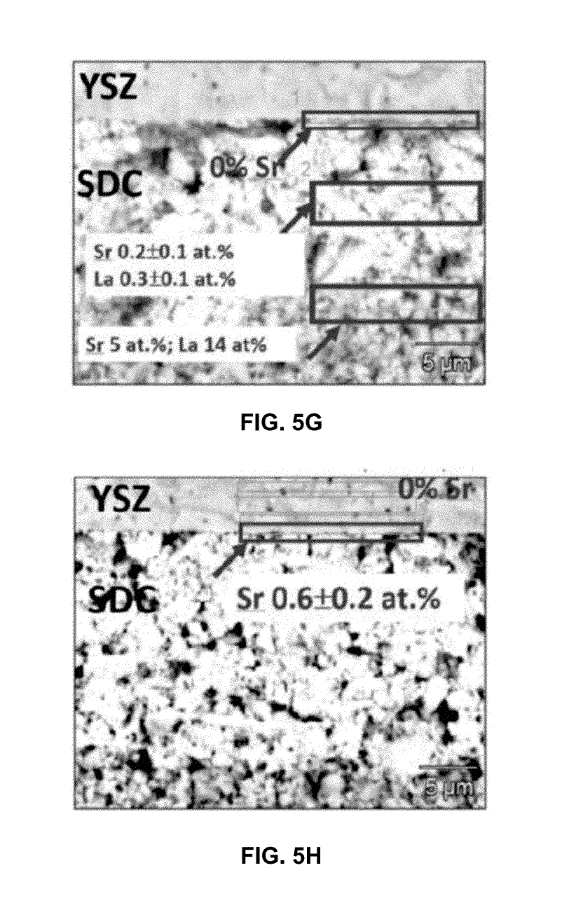

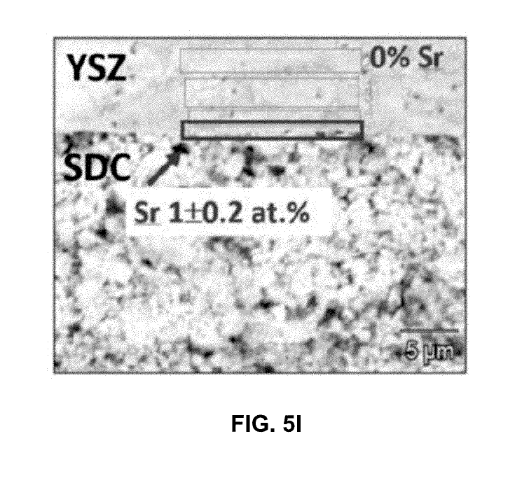

Testing materials and results are shown in FIG. 5A-FIG. 5I. A Cross sectional image of a representative LSCF-based single cell is shown at FIG. 5A. The inserted image is the Au-grid on LSCF.

The electrochemical performance of each LSCF was measured every 50 hours at 750° C. The electrochemical performance of LSCF-1 is shown at FIG. 5B and of LSCF-III is shown at FIG. 5C. FIGS. 5D, 5E, and 5F are initial EIS spectra and these measured at various times for LSCF-I, -II, and -III, respectively.

FIG. 5G, FIG. 5H, and FIG. 5I are analyses of the concentration of Sr at the interfaces between YSZ and doped ceria for LSCF-I, -II, and -III, respectively.

The SDC layer was used to inhibit interaction between LSCF and YSZ to form insulating SrZrO₃ or diffusion of Zr into LSCF. Observation of Sr at the interfaces between YSZ and SDC was thus a surprise. Furthermore, Sr concentration, shown in FIG. 5H and FIG. 5I at the interfaces was much higher in these cells after the fast cycling measurements than in LSCF-1 with slow cycling.

Sr segregation was observed in fast cycling measurements at both high (1 A/cm²) and low (0.5 A/cm²) current densities for 200 hours, which was equivalent to the measurements of the single cells measured for 3,000 hours. More importantly, high current appeared to result in a rapid segregation, thus fast increases in the ohmic loss.

Segregation was not detected at the YSZ/SDC interfaces in steady state operation at 1 A/cm² for 200 hours, but was observed in our previous studies for 3,000 hour operation.

FIG. 5D, FIG. 5E and FIG. 5F show that the cycling frequency played a more important role than the current density in these cells. The ohmic loss increases continuously with time under fast cycles, as shown in FIG. 5D, FIG. 5E and FIG. 5F.

### Example 2

Cells were fabricated as described above, save that the cathode was formed of doped (Pr_{0.50}Nd_{0.50})₂NiO₄ (PNNO5050). A first cell (PNNO-III) was held at a constant current of 0.75 A/cm² at 790° C. A second cell (PNNO-II) was operated under fast cycling at 0.5 A/cm² loading for 2-sec, followed by 1-sec at 0 A/cm² at 790° C.

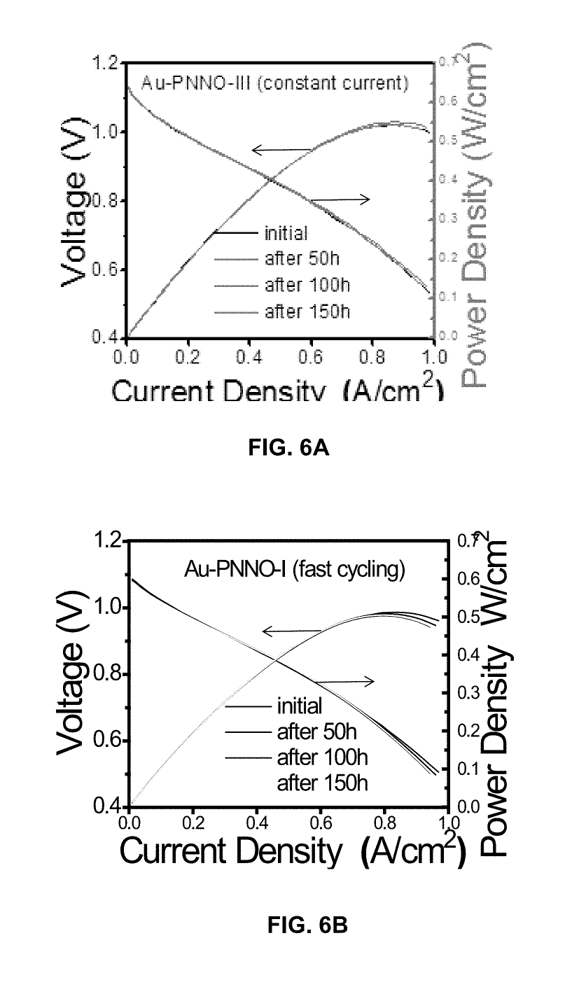

FIG. 6A and FIG. 6B show the effects on the two PNNO cathode testing protocols in an anode supported button cell with an active cathode area of 2 cm².

While the subject matter has been described in detail with respect to the specific embodiments thereof, it will be appreciated that those skilled in the art, upon attaining an understanding of the foregoing, may readily conceive of alterations to, variations of, and equivalents to these embodiments. Accordingly, the scope of the present disclosure should be assessed as that of the appended claims and any equivalents thereto.

What is claimed is:

1. An accelerated cathode testing protocol comprising cycling a solid oxide fuel cell multiple times between an open circuit voltage and an operating potential at an operating current density, the operating current density being about 0.15 A/cm² or greater, each cycle including a first time period at the open circuit voltage and a second time period at the operating potential, wherein the second time period is longer than the first time period.

2. The protocol of claim 1, wherein the second time period is about 1 minute or less.

3. The protocol of claim 1, wherein the testing protocol is carried out over a total time period of about 500 hours or less and/or for about 500,000 cycles or less.

4. The protocol of claim 1, wherein the testing protocol is carried out at a temperature of from about 600° C. to about 870° C.

5. The protocol of claim 1, wherein the operating current density is from about 0.15 A/cm² to about 3 A/cm².

6. The protocol of claim 1, further comprising carrying out the testing protocol multiple times, wherein the operating current density is varied between each protocol.

7. The protocol of claim 1, the method comprising flowing a fuel to the anode side of the solid oxide fuel cell and flowing an oxidant to the cathode side of the solid oxide fuel cell, wherein the relative humidity of the fuel and/or the oxidant is from 0% to about 5% relative humidity and a volatile species is optionally included in the fuel and/or the oxidant.

8. The protocol of claim 1, wherein the solid oxide fuel cell is a single or stacked planar or tubular cell.

9. The protocol of claim 1, wherein the cathode is lanthanum based, gadolinium based, praseodymium based, strontium based, or yttria based.

10. The protocol of claim 1, further comprising examining the solid oxide fuel cell or the cathode according to one or more X-ray photoelectron spectroscopy, transmission electron microscopy, or scanning electron microscopy.

11. The protocol of claim 1, further comprising determining one or more of:
a polarization curve of the solid oxide fuel cell one or more times throughout the testing protocol,
the impedance response of the solid oxide fuel cell one or more times throughout the testing protocol,
the area specific resistance of the solid oxide fuel cell during the testing protocol, and
a differential relaxation time analysis on electrochemical characteristics of the solid oxide fuel cell.

12. An accelerated cathode testing protocol comprising cycling a solid oxide fuel cell multiple times between an open circuit voltage and an operating potential at an operating current density, each cycle including a first time period at the open circuit voltage and a second time period at the operating potential, wherein the second time period is about 1 minute or less and the second time period is longer than the first time period.

13. The protocol of claim 12, wherein the ratio of the second time period to the first time period is from about 5:1 to about 2:1 and wherein the testing protocol is carried out over a total time period of about 500 hours or less and/or for about 500,000 cycles or less.

14. The protocol of claim 12, wherein the testing protocol is carried out at a temperature of from about 600° C. to about 870° C.

15. The protocol of claim 12, wherein the operating current density is from about 0.15 A/cm² to about 3 A/cm².

16. The protocol of claim 12, further comprising carrying out the testing protocol multiple times, wherein the first time period and/or the second time period is varied between each protocol.

17. The protocol of claim 12, the protocol comprising flowing a fuel to the anode side of the solid oxide fuel cell and flowing an oxidant to the cathode side of the solid oxide fuel cell, wherein the relative humidity of the fuel and/or the oxidant is from 0% to about 5% relative humidity and a volatile species is optionally included in the fuel and/or the oxidant.

18. The protocol of claim 12, wherein the solid oxide fuel cell is a single or a stacked planar or a tubular cell.

19. The protocol of claim 12, wherein the cathode is lanthanum based, gadolinium based, praseodymium based, strontium based, or yttria based.

20. The protocol of claim 12, further comprising examining the solid oxide fuel cell or the cathode according to one or more X-ray photoelectron spectroscopy, transmission electron microscopy, or scanning electron microscopy.

21. The protocol of claim 12, further comprising determining one or more of the following:
a polarization curve of the solid oxide fuel cell one or more times throughout the testing protocol,
the impedance response of the solid oxide fuel cell one or more times throughout the testing protocol,
the area specific resistance of the solid oxide fuel cell during the testing protocol, and
a differential relaxation time analysis on electrochemical characteristics of the solid oxide fuel cell.
